(19) United States
(12) Patent Application Publication
(10) Pub. No.: US 2026/0206442 A1
(43) Pub. Date: Jul. 16, 2026

(54) DISPLAY DEVICE, ELECTRONIC DEVICE, AND METHOD OF FABRICATING THE DISPLAY DEVICE

(71) Applicant: Samsung Display Co., Ltd., Yongin-si (KR)

(72) Inventor: Chun Gi YOU, Yongin-si (KR)

(21) Appl. No.: 19/423,422

(22) Filed: Dec. 17, 2025

(30) Foreign Application Priority Data
Jan. 16, 2025 (KR) 10-2025-0006642

(51) Int. Cl. H10K 59/131; H10K 59/12; H10K 59/122; H10K 59/32; H10K 59/80; H10K 102/00

(52) U.S. Cl. CPC H10K 59/131; H10K 59/1201; H10K 59/122; H10K 59/32; H10K 59/80515; H10K 2102/351

(57) ABSTRACT

A display device includes: a substrate having a display area and a non-display area; a connection electrode on the display area of the substrate; a reflective electrode on the connection electrode; a capping layer on the reflective electrode; a first electrode on the capping layer; a pixel defining layer on the first electrode and defining an emission area which exposes the first electrode; a light emitting stack on the first electrode and the pixel defining layer; a second electrode on the light emitting stack; and a pad on a pad portion of the non-display area of the substrate, wherein the pad comprises a pad electrode comprising the same material as the reflective electrode.

### CROSS-REFERENCE TO RELATED APPLICATION

The present application claims priority to and the benefit of Korean Patent Application No. 10-2025-0006642, filed on January 16, 2025, in the Korean Intellectual Property Office, the entire disclosure of which is incorporated herein by reference.

### BACKGROUND

### 1. Field

Aspects of some embodiments of the present disclosure relate to a display device, an electronic device, and a method of fabricating a display device.

### 2. Description of the Related Art

An organic light emitting display apparatus includes a display element whose luminance varies according to an electric current, for example, an organic light emitting diode.

The above information disclosed in this Background section is only for enhancement of understanding of the background and therefore the information discussed in this Background section does not necessarily constitute prior art.

### SUMMARY

Aspects of some embodiments of the present disclosure relate to a display device, an electronic device, and a method of fabricating a display device, and for example, to a display device that may be fabricated at a relatively reduced cost, an electronic device, and a method of fabricating the display device.

Aspects of some embodiments of the present disclosure include a display device that may be fabricated at a relatively reduced cost, an electronic device, and a method of fabricating the display device.

However, aspects of embodiments according to the present disclosure are not restricted to those specifically set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes: a substrate having a display area and a non-display area; a connection electrode on the display area of the substrate; a reflective electrode on the connection electrode; a capping layer on the reflective electrode; a first electrode on the capping layer; a pixel defining layer located on the first electrode and defining an emission area which exposes the first electrode; a light emitting stack on the first electrode and the pixel defining layer; a second electrode on the light emitting stack; and a pad located on a pad portion of the non-display area of the substrate, wherein the pad includes a pad electrode including the same material as the reflective electrode.

According to some embodiments of the present disclosure, an electronic device includes a display device which includes a screen, wherein the display device includes: a substrate having a display area and a non-display area; a connection electrode on the display area of the substrate; a reflective electrode on the connection electrode; a capping layer on the reflective electrode; a first electrode on the capping layer; a pixel defining layer located on the first electrode and defining an emission area which exposes the first electrode; a light emitting stack on the first electrode and the pixel defining layer; a second electrode on the light emitting stack; and a pad located on a pad portion of the non-display area of the substrate, wherein the pad includes a pad electrode including the same material as the reflective electrode.

According to some embodiments of the present disclosure, in a method of fabricating a display device, the method includes: forming a connection electrode layer on a substrate having a display area and a non-display area; forming a reflective electrode layer on the connection electrode layer; forming a buffer electrode layer on the reflective electrode layer; forming a buffer electrode in a pad portion of the non-display area by patterning the buffer electrode layer; forming an auxiliary layer on the buffer electrode and the reflective electrode layer; and forming a connection electrode, a reflective electrode and a capping layer in the display area and forming a pad connection electrode, a pad electrode and a capping layer in the pad portion by patterning the connection electrode layer, the reflective electrode layer, and the auxiliary layer.

According to some embodiments, because a reflective electrode of a display area and a pad electrode of a pad portion can be formed together through a same process, the number of masks can be relatively reduced. Accordingly, a display device and an electronic device can be fabricated at a relatively reduced cost.

The characteristics of embodiments according to the present disclosure are not limited to the above-described characteristics and other characteristics which are not described herein will become more apparent to those skilled in the art from the following description.

### BRIEF DESCRIPTION OF THE DRAWINGS

These and/or other aspects will become more apparent and more readily appreciated from the following description of the embodiments, taken in conjunction with the accompanying drawings in which:

FIG. 1 is an exploded perspective view of a display device according to some embodiments;

FIG. 2 is a block diagram of the display device according to some embodiments;

FIG. 3 is an equivalent circuit diagram of a first subpixel according to some embodiments;

FIG. 4 is a layout view of an example of a display panel according to some embodiments;

FIGS. 5 and 6 are layout views of embodiments of a display area of FIG. 4;

FIG. 7 is a cross-sectional view of an example of the display panel taken along the line I1-I1’ of FIG. 5;

FIG. 8 is a detailed cross-sectional view of the area A1 of FIG. 7;

FIG. 9 is a detailed cross-sectional view of the area A2 of FIG. 8;

FIG. 10 is a cross-sectional view of an example of the display panel taken along the line I2-I2’ of FIG. 4;

FIGS. 11, 12, 13, 14, 15, 16, 17, 18, 19 and 20 are process views illustrating a method of fabricating a display device according to some embodiments;

FIG. 21 is a block diagram of an electronic device according to some embodiments; and

FIGS. 22, 23, and 24 are schematic diagrams of electronic devices according to some embodiments.

### DETAILED DESCRIPTION

The present invention will now be described more fully hereinafter with reference to the accompanying drawings, in which aspects of some embodiments of the present disclosure. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification. In the attached figures, the thickness of layers and regions is exaggerated for clarity.

Although the terms "first", "second", etc. may be used herein to describe various elements, these elements, should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

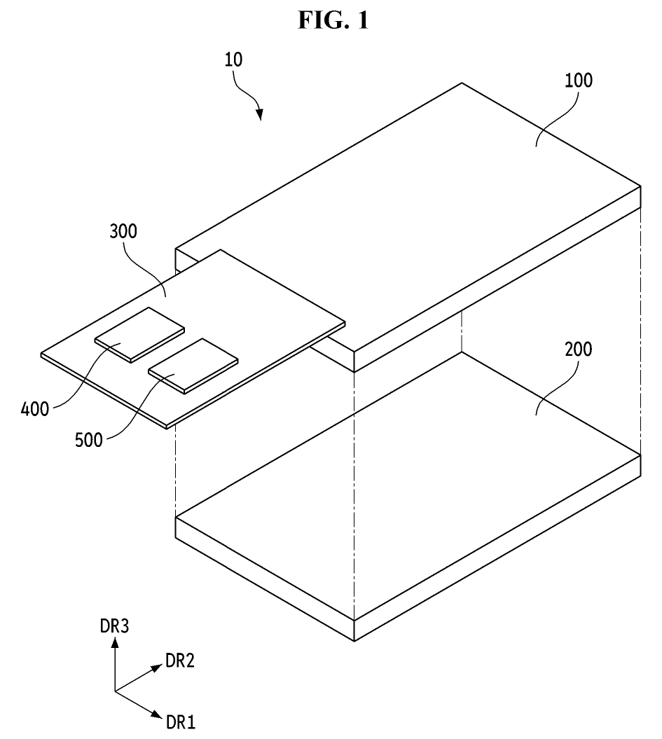

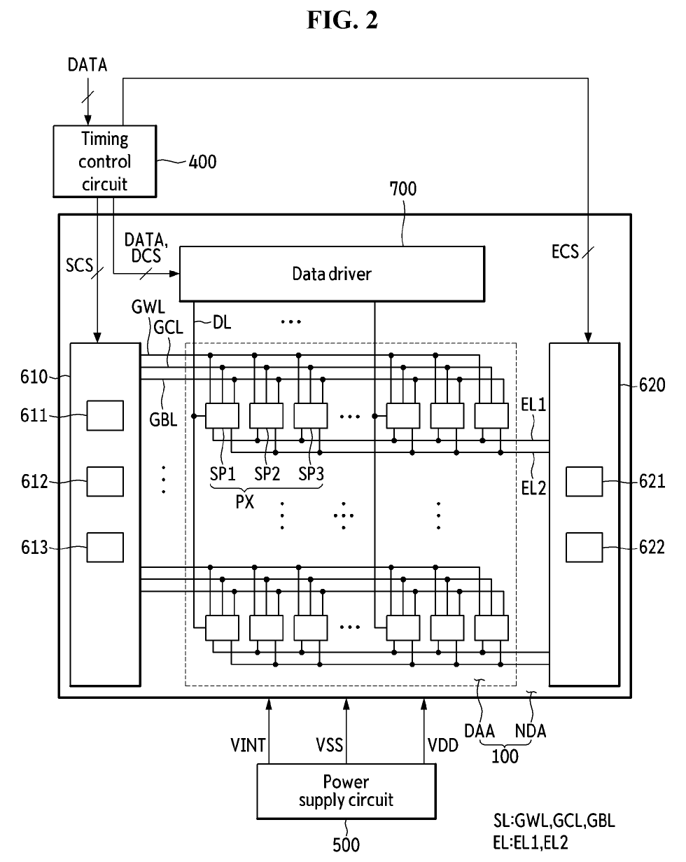

FIG. 1 is an exploded perspective view of a display device 10 according to some embodiments. FIG. 2 is a block diagram of the display device 10 according to some embodiments.

Referring to FIGS. 1 and 2, the display device 10 according to some embodiments is a device for displaying moving images (e.g., video images) or still images (e.g., static images). The display device 10 according to some embodiments may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to some embodiments may be applied as a display unit of a television, a notebook computer, a monitor, a billboard, or an Internet of things (IoT) device. Alternatively, the display device 10 according to some embodiments may be applied to smart watches, watch phones, and head mounted displays for implementing virtual reality and augmented reality.

The display device 10 according to some embodiments may include a display panel 100, a heat dissipation layer 200, a circuit board 300, a timing control circuit 400, and a power supply circuit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded with a selected curvature or may be right-angled. The planar shape of the display panel 100 is not limited to a quadrangular shape and may also be similar to other polygonal shapes, a circular shape, or an oval shape. The planar shape of the display device 10 may follow the planar shape of the display panel 100, but embodiments of the present specification are not limited thereto.

The display panel 100 includes a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying images and a non-display area NDA not displaying images. According to some embodiments, the non-display area NDA may surround (e.g., in a periphery or outside a footprint of) the display area DAA.

The pixels PX may be arranged in the display area DAA. The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL include a plurality of write scan lines GWL, a plurality of control scan lines GCL, and a plurality of bias scan lines GBL. The emission control lines EL include a plurality of first emission control lines EL1 and a plurality of second emission control lines EL2.

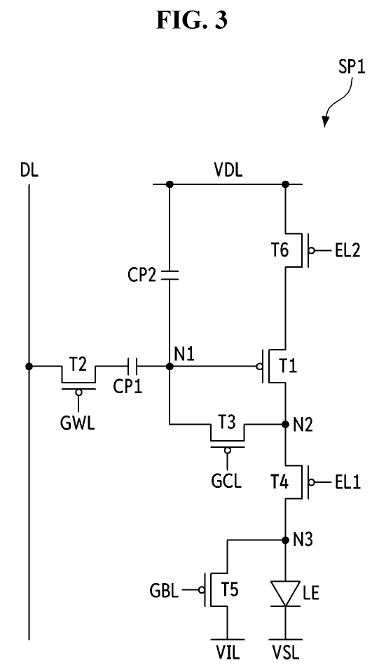

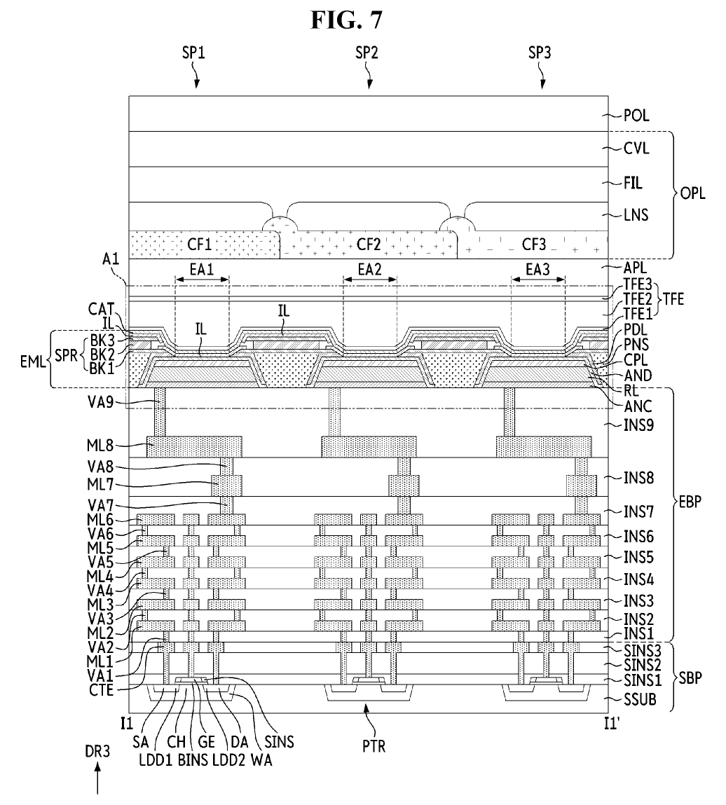

Each of the pixels PX includes a plurality of subpixels SP1 through SP3. Each of the subpixels SP1 through SP3 includes a plurality of pixel transistors as illustrated in FIG. 3. The pixel transistors may be formed through a semiconductor process and may be located in a semiconductor substrate SSUB (see FIG. 7). For example, the pixel transistors may be formed as complementary metal oxide semiconductor (CMOS) transistors, but embodiments of the present specification are not limited thereto.

Each of the subpixels SP1 through SP3 may be connected to any one of the write scan lines GWL, any one of the control scan lines GCL, any one of the bias scan lines GBL, any one of the first emission control lines EL1, any one of the second emission control lines EL2, and any one of the data lines DL. Each of the subpixels SP1 through SP3 may receive a data voltage of a data line DL according to a write scan signal of a write scan line GWL and emit light from a light emitting element according to the data voltage.

The scan driver 610, the emission driver 620, and the data driver 700 may be located in the non-display area NDA.

The scan driver 610 includes a plurality of scan transistors, and the emission driver 620 includes a plurality of emission transistors. The scan transistors and the emission transistors may be formed through a semiconductor process and may be formed in the semiconductor substrate SSUB (see FIG. 7). For example, the scan transistors and the emission transistors may be formed as CMOS transistors, but embodiments of the present specification are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driving unit 621 and a second emission control driving unit 622. Each of the first emission control driving unit 621 and the second emission control driving unit 622 may receive an emission timing control signal ECS from the timing control circuit 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 includes a plurality of data transistors. The data transistors may be formed through a semiconductor process and may be formed in the semiconductor substrate SSUB (see FIG. 7). For example, the data transistors may be formed as CMOS transistors, but embodiments of the present specification are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be located on a surface, e.g., a back surface of the display panel 100. The heat dissipation layer 200 dissipates heat generated from the display panel 100. The heat dissipation layer 130 may include a metal layer having high thermal conductivity, such as graphite, silver (Ag), copper (Cu), or aluminum (Al).

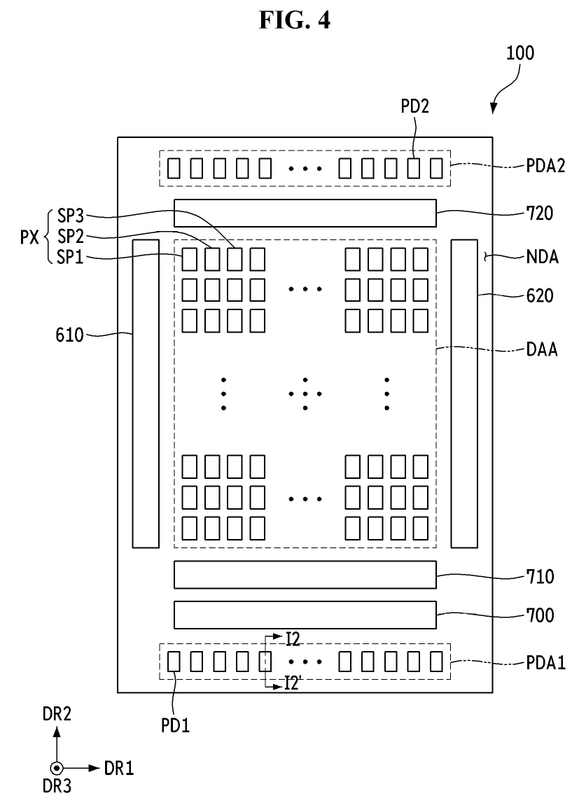

The circuit board 300 may be electrically connected to a plurality of first pads PD1 (see FIG. 4) in a first pad portion PDA1 (see FIG. 4) of the display panel 100 by using a conductive adhesive member such as an anisotropic conductive film. The circuit board 300 may be a flexible printed circuit board or a flexible film. Although the circuit board 300 is unfolded in FIG. 1, it may also be bent. In this case, one end of the circuit board 300 may be placed on the back surface of the display panel 100 and/or a back surface of the heat dissipation layer 200. The other end of the circuit board 300 may be connected to the first pads PD1 (see FIG. 4) of the first pad portion PDA1 (see FIG. 4) of the display panel 100 by using a conductive adhesive member. The one end of the circuit board 300 may be an end opposite the other end of the circuit board 300.

The timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and the emission timing control signal ECS to the emission driver 620. The timing control circuit 400 may output the digital video data and the data timing control signal DCS to the data driver 700.

The power supply circuit 500 may generate a plurality of panel driving voltages according to a power supply voltage received from the outside. For example, the power supply circuit 500 may generate a first driving voltage VSS, a second driving voltage VDD and a third driving voltage VINT and supply them to the display panel 100. The first driving voltage VSS, the second driving voltage VDD, and the third driving voltage VINT will be described later with reference to FIG. 3.

Each of the timing control circuit 400 and the power supply circuit 500 may be formed as an integrated circuit and attached to a surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, the timing control circuit 400 and the power supply circuit 500 may be located in the non-display area NDA of the display panel 100, like the scan driver 610, the emission driver 620, and the data driver 700. In this case, the timing control circuit 400 may include a plurality of timing transistors, and the power supply circuit 500 may include a plurality of power transistors. The timing transistors and the power transistors may be formed through a semiconductor process and may be formed in the semiconductor substrate SSUB (see FIG. 7). For example, the timing transistors and the power transistors may be formed as CMOS transistors, but embodiments of the present specification are not limited thereto. Each of the timing control circuit 400 and the power supply circuit 500 may be located between the data driver 700 and the first pad portion PDA1 (see FIG. 4).

FIG. 3 is an equivalent circuit diagram of a first subpixel SP1 according to some embodiments. Although FIG. 3 illustrates various components in a subpixel according to some embodiments, embodiments according to the present disclosure are not limited thereto, and according to various embodiments, the subpixel may include additional components or fewer components without departing from the spirit and scope of embodiments according to the present disclosure.

Referring to FIG. 3, the first subpixel SP1 may be connected to a write scan line GWL, a control scan line GCL, a bias scan line GBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

The first subpixel SP1 includes a plurality of transistors T1 through T6, a light emitting element LE, a first capacitor CP1, and a second capacitor CP2.

The light emitting element LE emits light according to a driving current Ids flowing through a channel of a first transistor T1. The amount of light emitted from the light emitting element LE may be proportional to the driving current Ids. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. The light emitting element LE may be an organic light emitting diode including a first electrode, a second electrode, and an organic light emitting layer located between the first electrode and the second electrode. However, embodiments of the present specification are not limited thereto. For example, the light emitting element LE may be an inorganic light emitting element including a first electrode, a second electrode, and an inorganic semiconductor located between the first electrode and the second electrode. In this case, the light emitting element LE may be a micro light emitting diode.

The first transistor T1 may be a driving transistor that controls a source-drain current Ids (hereinafter, referred to as a “driving current”) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL and connects the electrode of the first capacitor CP1 to the data line DL. Accordingly, a data voltage of the data line DL may be applied to the electrode of the first capacitor CP1. The second transistor T2 includes a gate electrode connected to the write scan line GWL, a source electrode connected to the data line DL, and a drain electrode connected to the electrode of the first capacitor CP1.

A third transistor T3 may be located between the first node N1 and the second node N2. The third transistor T3 is turned on by a write control signal of the write control line GCL and connects the first node N1 to the second node N2. Accordingly, when the gate electrode and source electrode of the first transistor T1 are connected, the first transistor T1 may operate as a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, embodiments of the present specification are not limited thereto. Each of the first through sixth transistors T1 through T6 may also be an N-type MOSFET. Alternatively, some of the first through sixth transistors T1 through T6 may be P-type MOSFETs, and the other transistors may be N-type MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors in the first subpixel SP1 are not limited to those illustrated in FIG. 3.

In addition, an equivalent circuit diagram of a second subpixel SP2 and an equivalent circuit diagram of a third subpixel SP3 may be the same (or substantially the same) as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the present specification.

FIG. 4 is a layout view of an example of a display panel 100 according to some embodiments.

Referring to FIG. 4, a display area DAA of the display panel 100 according to some embodiments includes a plurality of pixels PX arranged in a matrix form. A non-display area NDA of the display panel 100 according to some embodiments includes a scan driver 610, an emission driver 620, a data driver 700, a first distribution circuit 710, a second distribution circuit 720, a first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on a left side of the display area DAA, and the emission driver 620 may be located on a right side of the display area DAA. However, embodiments of the present specification are not limited thereto, and the scan driver 610 and the emission driver 620 may also be located on both the first and second sides of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2. That is, the first pad portion PDA1 may be located closer to an edge of the display panel 100 than the data driver 700.

The second pad portion PDA2 may include a plurality of second pads PD2 corresponding to test pads for testing whether the display panel 100 operates normally. The second pads PD2 may be connected to a jig or a probe pin during a test process or may be connected to a test circuit board. The test circuit board may be a rigid printed circuit board or a flexible printed circuit board.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2. That is, the second pad portion PDA2 may be located closer to an edge of the display panel 100 than the second distribution circuit 720.

The first distribution circuit 710 distributes data voltages received through the first pad portion PDA1 to a plurality of data lines DL. For example, the first distribution circuit 710 may distribute data voltages received through one first pad PD1 of the first pad portion PDA1 to P (P is a positive integer of 2 or more) data lines DL. Therefore, the number of first pads PD1 can be relatively reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 distributes signals received through the second pad portion PDA2 to the scan driver 610, the emission driver 620, and the data lines DL. The second pad portion PDA2 and the second distribution circuit 720 may be elements for testing the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on an upper side of the display area DAA.

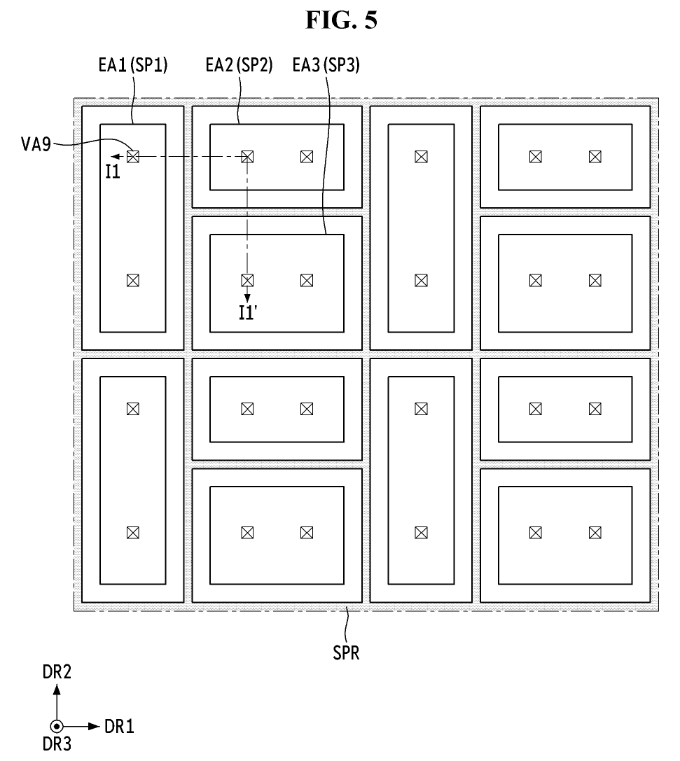

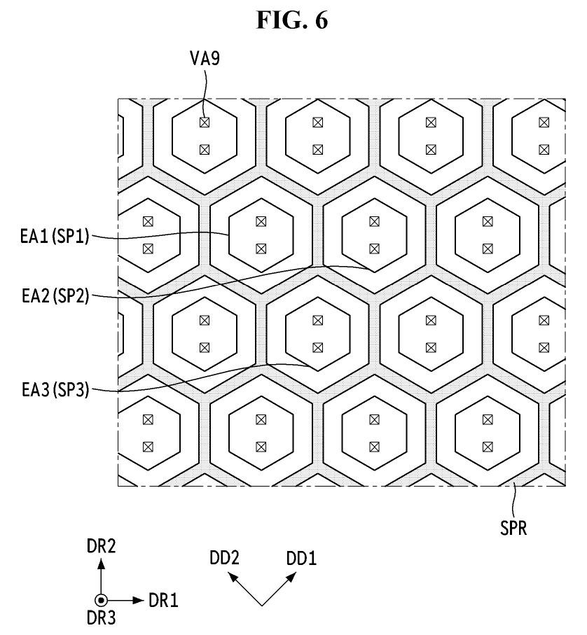

FIGS. 5 and 6 are layout views of embodiments of the display area DAA of FIG. 4.

Referring to FIGS. 5 and 6, each of a plurality of pixels PX includes a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular planar shape.

A maximum length of the first emission area EA1 in the first direction DR1 may be smaller than a maximum length of the second emission area EA2 in the first direction DR1 and a maximum length of the third emission area EA3 in the first direction DR1. The maximum length of the second emission area EA2 in the first direction DR1 may be equal (or substantially equal) to the maximum length of the third emission area EA3 in the first direction DR1.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have a hexagonal planar shape composed of six straight lines as illustrated in FIGS. 5 and 6. However, embodiments of the present specification are not limited thereto. The first emission area EA1, the second emission area EA2, and the third emission area EA3 may also have a polygonal planar shape other than a hexagonal shape or a circular, oval or irregular planar shape.

As illustrated in FIG. 5, in each of the pixels PX, the first emission area EA1 and the second emission area EA2 may neighbor each other in the first direction DR1. In addition, the first emission area EA1 and the third emission area EA3 may neighbor each other in the first direction DR1. In addition, the second emission area EA2 and the third emission area EA3 may neighbor each other in the second direction DR2. The area of the first emission area EA1, the area of the second emission area EA2, and the area of the third emission area EA3 may be different.

Alternatively, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined at 45 degrees with respect to the first direction DR1 and the second direction DR2. The second diagonal direction DD2 may be a direction orthogonal to the first diagonal direction DD1.

The first subpixel SP1 may output first light that has passed through a first color filter CF1 (see FIG. 7) among light emitted from the first emission area EA1, the second subpixel SP2 may output second light that has passed through a second color filter CF2 (see FIG. 7) among light emitted from the second emission area EA2, and the third subpixel SP3 may output third light that has passed through a third color filter CF3 (see FIG. 7) among light emitted from the third emission area EA3.

The first light, the second light, and the third light may be light of different wavelength bands. For example, any one of the first light, the second light and the third light may be light in a blue wavelength band, another may be light in a green wavelength band, and the other may be light in a red wavelength band. Here, the blue wavelength band may indicate that a main peak wavelength of light is included in a wavelength band of 370 to 460 nanometers (nm) (or about 370 to 460 nm), the green wavelength band may indicate that a main peak wavelength of light is included in a wavelength band of 480 to 560 nm (or about 480 to 560 nm), and the red wavelength band may indicate that a main peak wavelength of light is included in a wavelength band of about 600 to 750 nm.

Although each of the pixels PX includes three emission areas EA1 through EA3 in FIGS. 5 and 6, embodiments of the present specification are not limited thereto. That is, each of the pixels PX may also include four emission areas.

In addition, the arrangement of the emission areas of the pixels PX is not limited to those illustrated in FIGS. 5 and 6. For example, the emission areas of the pixels PX may also be arranged in a stripe structure in which emission areas are arranged in the first direction DR1, in a PenTile® structure in which emission areas are arranged in a diamond shape, or in a hexagonal structure in which emission areas having a hexagonal planar shape are arranged as illustrated in FIG. 6.

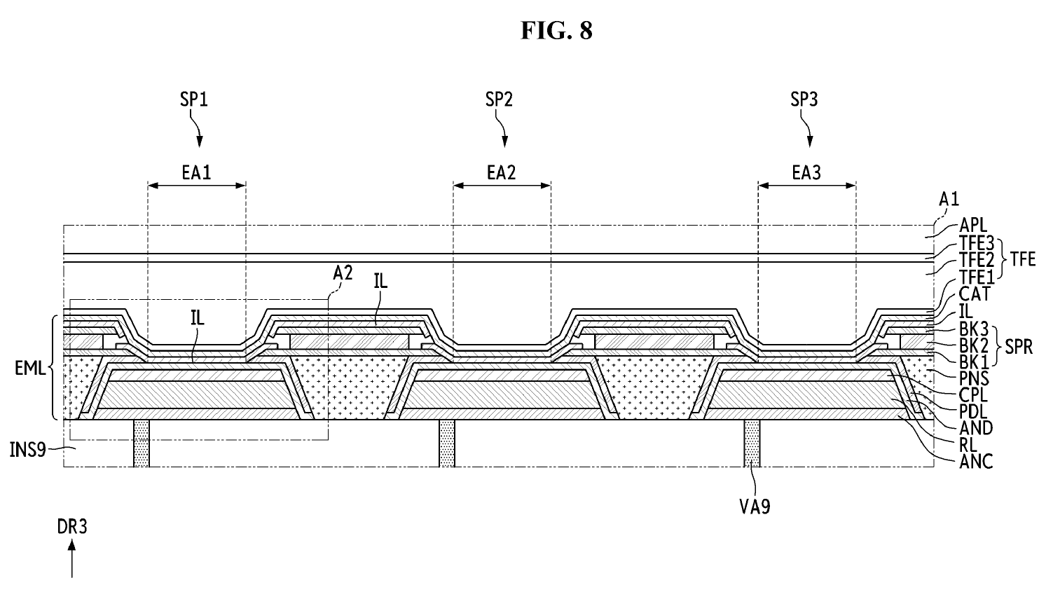

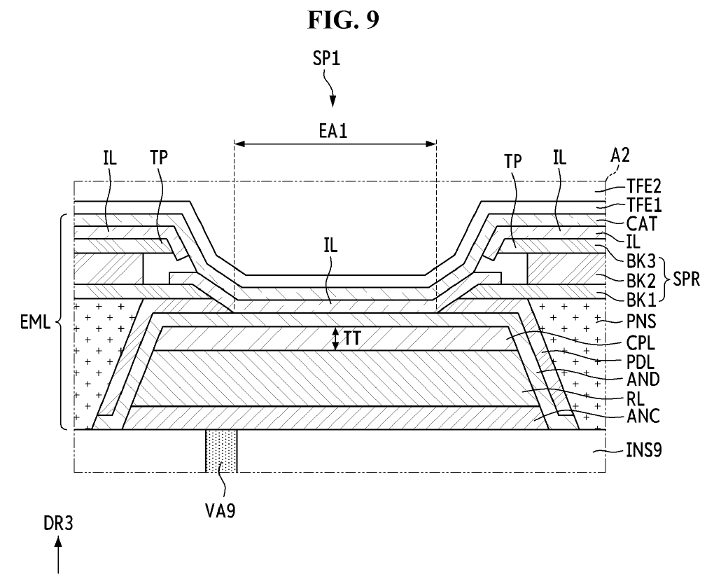

FIG. 7 is a cross-sectional view of an example of the display panel 100 taken along the line I1-I1’ of FIG. 5. FIG. 8 is a detailed cross-sectional view of area A1 of FIG. 7. FIG. 9 is a detailed cross-sectional view of area A2 of FIG. 8.

Referring to FIGS. 7 through 9, the display panel 100 includes a semiconductor backplane SBP, a light emitting element backplane EBP, a display element layer EML, an encapsulation layer TFE, an optical layer OPL, a cover layer CVL, and a polarizer POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR. The pixel transistors PTR may be the first through sixth transistors T1 through T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be located in an upper surface of the semiconductor substrate SSUB. The well areas WA may be areas doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the well areas WA includes a source area SA corresponding to a source electrode of a pixel transistor PTR, a drain area DA corresponding to a drain electrode of the pixel transistor PTR, and a channel area CH located between the source area SA and the drain area DA.

A bottom insulating layer BINS may be located between a gate electrode GE and each well area WA. A side insulating layer SINS may be located on side surfaces of the gate electrode GE. The side insulating layer SINS may be located on the bottom insulating layer BINS.

Each of the source area SA and the drain area DA may be an area doped with the first-type impurities. The gate electrode GE of each pixel transistor PTR may overlap a well area WA in the third direction DR3 which is a thickness direction of the semiconductor substrate SSUB. The channel area CH may overlap the gate electrode GE in the third direction DR3. The source area SA may be located on one side of the gate electrode GE, and the drain area DA may be located on the other side of the gate electrode GE.

Each of the well areas WA further includes a first lightly doped impurity area LDD1 located between the channel area CH and the source area SA and a second lightly doped impurity area LDD2 located between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be located on the semiconductor substrate SSUB. The first semiconductor insulating layer SINS1 may include a silicon carbon nitride (SiCN) or silicon oxide (SiOₓ)-based inorganic layer, but embodiments of the present specification are not limited thereto.

A second semiconductor insulating layer SINS2 may be located on the first semiconductor insulating layer SINS1. The second semiconductor insulating layer SINS2 may include a silicon oxide (SiOₓ)-based inorganic layer, but embodiments of the present specification are not limited thereto.

The contact terminals CTE may be located on the second semiconductor insulating layer SINS2. Each of the contact terminals CTE may be connected to any one of the gate electrode GE, the source area SA, and the drain area DA of a pixel transistor PTR through a hole penetrating the first semiconductor insulating layer SINS1 and the second semiconductor insulating layer SINS2. The contact terminals CTE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may include a silicon oxide (SiOₓ)-based inorganic layer, but embodiments of the present specification are not limited thereto.

The semiconductor substrate SSUB can be replaced with a glass substrate or a polymer resin substrate such as polyimide. In this case, thin-film transistors may be located on the glass substrate or the polymer resin substrate. The glass substrate may be a rigid substrate that is not bent, and the polymer resin substrate may be a flexible substrate that can be bent or curved.

The light emitting element backplane EBP includes a plurality of conductive layers ML1 through ML8, a plurality of via electrodes VA1 through VA9, and a plurality of insulating layers INS1 through INS9. In addition, the light emitting element backplane EBP includes a plurality of insulating layers INS1 through INS9 located between first through eighth conductive layers ML1 through ML8.

The first through eighth conductive layers ML1 through ML8 implement the circuit of the first subpixel SP1 illustrated in FIG. 3 by connecting the contact terminals CTE exposed in the semiconductor backplane SBP. For example, the first through sixth transistors T1 through T6 are simply formed in the semiconductor backplane SBP, and the connection of the first through sixth transistors T1 through T6 and the first and second capacitors CP1 and CP2 are achieved through the first through eighth conductive layers ML1 through ML8. In addition, the connection between a drain area corresponding to the drain electrode of the fourth transistor T4, a source area corresponding to the source electrode of the fifth transistor T5, and the first electrode AND of the light emitting element LE is achieved through the first through eighth conductive layers ML1 through ML8.

A first insulating layer INS1 may be located on the semiconductor backplane SBP. First via electrodes VA1 may penetrate the first insulating layer INS1 and may be respectively connected to the contact terminals CTE exposed in the semiconductor backplane SBP. The first conductive layers ML1 may be located on the first insulating layer INS1 and may be connected to the first via electrodes VA1, respectively.

A second insulating layer INS2 may be located on the first insulating layer INS1 and the first conductive layers ML1. Second via electrodes VA2 may penetrate the second insulating layer INS2 and may be connected to the exposed first conductive layers ML1, respectively. The second conductive layers ML2 may be located on the second insulating layer INS2 and may be connected to the second via electrodes VA2, respectively.

A third insulating layer INS3 may be located on the second insulating layer INS2 and the second conductive layers ML2. Third via electrodes VA3 may penetrate the third insulating layer INS3 and may be connected to the exposed second conductive layers ML2, respectively. The third conductive layers ML3 may be located on the third insulating layer INS3 and may be connected to the third via electrodes VA3, respectively.

A fourth insulating layer INS4 may be located on the third insulating layer INS3 and the third conductive layers ML3. Fourth via electrodes VA4 may penetrate the fourth insulating layer INS4 and may be connected to the exposed third conductive layers ML3, respectively. The fourth conductive layers ML4 may be located on the fourth insulating layer INS4 and may be connected to the fourth via electrodes VA4, respectively.

A fifth insulating layer INS5 may be located on the fourth insulating layer INS4 and the fourth conductive layers ML4. Fifth via electrodes VA5 may penetrate the fifth insulating layer INS5 and may be connected to the exposed fourth conductive layers ML4, respectively. The fifth conductive layers ML5 may be located on the fifth insulating layer INS5 and may be connected to the fifth via electrodes VA5, respectively.

A sixth insulating layer INS6 may be located on the fifth insulating layer INS5 and the fifth conductive layers ML5. Sixth via electrodes VA6 may penetrate the sixth insulating layer INS6 and may be connected to the exposed fifth conductive layers ML5, respectively. The sixth conductive layers ML6 may be located on the sixth insulating layer INS6 and may be connected to the sixth via electrodes VA6, respectively.

A seventh insulating layer INS7 may be located on the sixth insulating layer INS6 and the sixth conductive layers ML6. Each of seventh via electrodes VA7 may penetrate the seventh insulating layer INS7 and may be connected to an exposed sixth conductive layer ML6. The seventh conductive layers ML7 may be located on the seventh insulating layer INS7 and may be connected to the seventh via electrodes VA7, respectively.

An eighth insulating layer INS8 may be located on the seventh insulating layer INS7 and the seventh conductive layers ML7. Eighth via electrodes VA8 may penetrate the eighth insulating layer INS8 and may be connected to the exposed seventh conductive layers ML7, respectively. The eighth conductive layers ML8 may be located on the eighth insulating layer INS8 and may be connected to the eighth via electrodes VA8, respectively.

The first through eighth conductive layers ML1 through ML8 and the first through eighth via electrodes VA1 through VA8 may include the same (or substantially the same) material. The first through eighth conductive layers ML1 through ML8 and the first through eighth via electrodes VA1 through VA8 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. The first through eighth via electrodes VA1 through VA8 may include the same (or substantially the same) material. The first through eighth insulating layers INS1 through INS8 may include a silicon oxide (SiOₓ)-based inorganic layer, but embodiments of the present specification are not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than a thickness of the first via electrodes VA1, a thickness of the second via electrodes VA2, a thickness of the third via electrodes VA3, a thickness of the fourth via electrodes VA4, a thickness of the fifth via electrodes VA5, and a thickness of the sixth via electrodes VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be the same (or substantially the same). For example, the thickness of the first conductive layers ML1 may be 1,360 Å (or about 1,360 Å), and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be 1,440 Å (or about 1,440 Å). In addition, the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6 may each be 1,150 Å (or about 1,150 Å).

A thickness of the seventh conductive layers ML7 and a thickness of the eighth conductive layers ML8 may each be greater than the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6. The thickness of the seventh conductive layers ML7 and the thickness of the eighth conductive layers ML8 may each be greater than a thickness of the seventh via electrodes VA7 and a thickness of the eighth via electrodes VA8. The thickness of the seventh via electrodes VA7 and the thickness of the eighth via electrodes VA8 may each be greater than the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6. The thickness of the seventh conductive layers ML7 and the thickness of the eighth conductive layers ML8 may be the same (or substantially the same). For example, the thickness of the seventh conductive layers ML7 and the thickness of the eighth conductive layers ML8 may each be 9,000 Å (or about 9,000 Å). The thickness of the seventh via electrodes VA7 and the thickness of the eighth via electrodes VA8 may each be 6,000 Å (or about 6,000 Å).

A ninth insulating layer INS9 may be located on the eighth insulating layer INS8 and the eighth conductive layers ML8. The ninth insulating layer INS9 may include a silicon oxide (SiOₓ)-based inorganic layer, but embodiments of the present specification are not limited thereto.

Ninth via electrodes VA9 may penetrate the ninth insulating layer INS9 and may be connected to the exposed eighth conductive layers ML8, respectively. The ninth via electrodes VA9 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. A thickness of the ninth via electrodes VA9 may be 16,500 Å (or about 16,500 Å).

The display element layer EML may be located on the light emitting element backplane EBP. The display element layer EML may include a plurality of connection electrodes ANC, a plurality of reflective electrodes RL, a planarization layer PNS, a plurality of pixel defining layers PDL, a plurality of first electrodes AND, a light emitting stack IL, a second electrode CAT, and a separator SPR.

In addition, the display element layer EML may include a first emission area EA1, a second emission area EA2, and a third emission area EA3. Each of the first emission area EA1, the second emission area EA2, and the third emission area EA3 may be an area where a first electrode AND, the light emitting stack IL, and the second electrode CAT are sequentially stacked. Each of the first emission area EA1, the second emission area EA2, and the third emission area EA3 may be an area where a light emitting element LE including the first electrode AND, the light emitting stack IL, and the second electrode CAT is located. The first emission area EA1, the second emission area EA2, and the third emission area EA3 may be defined by the pixel defining layers PDL, respectively.

The connection electrodes ANC may be located on the ninth insulating layer INS9. For example, the connection electrodes ANC may be located on the ninth insulating layer INS9 such that they are connected to the ninth via electrodes VA9, respectively. The connection electrodes ANC may include titanium nitride (TiN) or a transparent conductive oxide. For example, the transparent conductive oxide may be indium tin oxide (ITO) or indium zinc oxide (IZO), but embodiments of the present specification are not limited thereto.

The reflective electrodes RL may be located on the connection electrodes ANC, respectively. For example, the reflective electrodes RL may be located between the connection electrodes ANC and capping layers CPL, respectively. Each of the reflective electrodes RL may include any one of copper (Cu), aluminum (Al), silver (Ag), tungsten (W), molybdenum (Mo), chromium (Cr), gold (Au), titanium (Ti), nickel (Ni) and neodymium (Nd) or may include an alloy including any one of the same. For example, each of the reflective electrodes RL may include aluminum (Al) or silver (Ag).

The capping layers CPL may be located on the reflective electrodes RL, respectively. For example, the capping layers CPL may be located on upper surfaces of the reflective electrodes RL. Thicknesses TT of the capping layers CPL in different subpixels may be equal to each other. For example, a thickness TT of a capping layer CPL overlapping the first emission area EA1 of a first subpixel SP1, a thickness of a capping layer CPL overlapping the second emission area EA2 of a second subpixel SP2, and a thickness of a capping layer CPL overlapping the third emission area EA3 of a third subpixel SP3 may be equal to each other. Each of the capping layers CPL may include a silicon oxide (SiOₓ)-based inorganic layer, but embodiments of the present specification are not limited thereto.

Each of light emitting elements LE may include a first electrode AND, the light emitting stack IL, and the second electrode CAT.

The first electrode AND may be located on a capping layer CPL. For example, the first electrode AND may be located on an upper surface of the capping layer CPL, side surfaces of the capping layer CPL, side surfaces of a reflective electrode RL, side surfaces of a connection electrode ANC, and an upper surface of the ninth insulating layer INS9. The first electrode AND may contact (or directly contact) the upper surface of the capping layer CPL, the side surfaces of the capping layer CPL, the side surfaces of the reflective electrode RL, the side surfaces of the connection electrode ANC, and the upper surface of the ninth insulating layer INS9. Because side surfaces of the first electrode AND and the side surfaces of the connection electrode ANC contact each other, the first electrode AND and the connection electrode ANC may be electrically connected to each other.

A thickness of the first electrode AND on the side surfaces of the capping layer CPL may be different from a thickness of the first electrode AND on the upper surface of the capping layer CPL. For example, the thickness of the first electrode AND on the side surfaces of the capping layer CPL may be smaller than the thickness of the first electrode AND on the upper surface of the capping layer CPL. Specifically, the thickness of the first electrode AND overlapping the side surfaces of the capping layer CPL may be smaller than the thickness of the first electrode AND overlapping the upper surface of the capping layer CPL.

The first electrode AND of each of the light emitting elements LE may be connected to the drain area DA or the source area SA of a pixel transistor PTR through the connection electrode ANC, the first through ninth via electrodes VA1 through VA9, the first through eighth conductive layers ML1 through ML8, and a contact terminal CTE.

The first electrode AND of each of the light emitting elements LE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the first electrode AND of each of the light emitting elements LE may be titanium nitride (TiN).

The pixel defining layers PDL may define the first through third emission areas EA1 through EA3. A pixel defining layer PDL may be located on a portion of the first electrode AND of each of the light emitting elements LE. The pixel defining layer PDL may cover edges of the first electrode AND of each of the light emitting elements LE. The pixel defining layers PDL may contact (or directly contact) the first electrodes AND. The pixel defining layers PDL may be located on the first electrodes AND. For example, the pixel defining layers PDL may be located on upper surfaces of the first electrodes AND and the side surfaces of the first electrodes AND. The first pixel defining layers PDL may include a material including silicon nitride (SiNₓ). The pixel defining layers PDL may include a different material from the planarization layer PNS which will be described later. Therefore, when the planarization layer PNS is removed by chemical mechanical polishing, the pixel defining layers PDL may function as etch-stop layers that define a thickness (or height) of the planarization layer PNS.

The first emission area EA1 may be defined as an area in the first subpixel SP1 where a first electrode AND, the light emitting stack IL, and the second electrode CAT are sequentially stacked to emit light. The second emission area EA2 may be defined as an area in the second subpixel SP2 where a first electrode AND, the light emitting stack IL, and the second electrode CAT are sequentially stacked to emit light. The third emission area EA3 may be defined as an area in the third subpixel SP3 where a first electrode AND, the light emitting stack IL, and the second electrode CAT are sequentially stacked to emit light.

The planarization layer PNS may be located between the first electrodes AND of the subpixels SP1 through SP3 to eliminate a step difference between the subpixels SP1 through SP3. For example, the planarization layer PNS may be located between the pixel defining layers PDL. The planarization layer PNS may include a material including silicon oxide (SiOₓ).

The separator SPR may be located on the pixel defining layers PDL and the planarization layer PNS. In plan view, as illustrated in FIGS. 5 and 6, the separator SPR may be shaped like a closed curve surrounding each of the emission areas EA1 through EA3. The separator SPR may be located on the pixel defining layers PDL and the planarization layer PNS to surround each of the emission areas EA1 through EA3. The separator SPR may be a structure for cutting the light emitting stack IL. To this end, according to some embodiments, the separator SPR may include a first bank BK1, a second bank BK2, and a third bank BK3 having different areas.

The first bank BK1 may be located on the pixel defining layers PDL and the planarization layer PNS. The first bank BK1 may include the same material as the planarization layer PNS. For example, the first bank BK1 may include a material including silicon oxide (SiOₓ). In this case, the first bank BK1 and the planarization layer PNS may be formed integrally without an interface.

The second bank BK2 may be located on the first bank BK1. The second bank BK2 may be located on the first bank BK1 to overlap the first bank BK1. Here, the area of the second bank BK2 may be smaller than the area of the first bank BK1. For example, the area of the second bank BK2 may be smaller than the area of the first bank BK1 so that the second bank BK2 can be surrounded by edges of the first bank BK1 in plan view. An etch rate of the second bank BK2 may be different from an etch rate of the first bank BK1. For example, the etch rate of the second bank BK2 may be higher than the etch rate of the first bank BK1. The second bank BK2 may include a material including silicon nitride (SiNₓ). Alternatively, the second bank BK2 may include a material including a metal. For example, the second bank BK2 may include a material including at least one of titanium (Ti), tantalum (Ta), or molybdenum (Mo).

The third bank BK3 may be located on the second bank BK2. The third bank BK3 may be located on the second bank BK2 to overlap the second bank BK2. Here, the area of the third bank BK3 may be larger than the area of the second bank BK2. For example, the area of the third bank BK3 may be larger than the area of the second bank BK2 so that the third bank BK3 can surround edges of the second bank BK2 in plan view. Accordingly, as illustrated in FIG. 9, the third bank BK3 may include tips TP not overlapping the second bank BK2. The etch rate of the second bank BK2 may be different from an etch rate of the third bank BK3. For example, the etch rate of the second bank BK2 may be higher than the etch rate of the third bank BK3. The third bank BK3 may include a material including silicon oxide (SiOₓ).

In a cross-section, the separator SPR including the first bank BK1, the second bank BK2 and the third bank BK3 may be narrower in the middle than at the top and bottom.

The light emitting stack IL may be located on the first electrodes AND, the pixel defining layers PDL, and the separator SPR. For example, the light emitting stack IL may be located on the first bank BK1 and the third bank BK3 of the separator SPR. The light emitting stack IL may be cut on the separator SPR. For example, the light emitting stack IL may be cut between the first bank BK1 and the third bank BK3. In plan view, the light emitting stack IL may be cut along the separator SPR. Therefore, the light emitting stack IL may be divided into a portion in contact with the first electrode AND in each emission area and a portion located on an area excluding the emission area (e.g., on the third bank BK3 of the separator SPR). In other words, the light emitting stack IL may be cut along the separator SPR so that it is separated for each subpixel. Accordingly, lateral leakage current between adjacent subpixels SP1 through SP3 can be minimized or relatively reduced. As the lateral leakage current is minimized or relatively reduced, a color mixing phenomenon between the adjacent subpixels SP1 through SP3 can be prevented or reduced, thereby relatively improving the image quality of the display device 10.

The light emitting stack IL may include a plurality of stack layers stacked sequentially along the third direction DR3. For example, the light emitting stack IL may have a three-tandem structure including a first stack layer, a second stack layer on the first stack layer, and a third stack layer on the second stack layer. Here, the second stack layer may be located between the first stack layer and the third stack layer. However, embodiments of the present specification are not limited thereto. For example, the light emitting stack IL may also have a two-tandem structure including two stack layers.

In the three-tandem structure, the first stack layer, the second stack layer, and the third stack layer of the light emitting stack IL may provide light of different colors (or wavelengths). For example, any one of the first stack layer, the second stack layer and the third stack layer may provide light of a first color (e.g., green), another stack layer may provide light of a second color (e.g., red), and the other stack layer may provide light of a third color (e.g., blue).

The first stack layer of the light emitting stack IL may have a structure in which a first hole transport layer, a first organic light emitting layer, and a first electron transport layer are sequentially stacked. The second stack layer of the light emitting stack IL may have a structure in which a second hole transport layer, a second organic light emitting layer, and a second electron transport layer are sequentially stacked. The third stack layer of the light emitting stack IL may have a structure in which a third hole transport layer, a third organic light emitting layer, and a third electron transport layer are sequentially stacked. Here, the first organic light emitting layer, the second organic light emitting layer, and the third organic light emitting layer may provide light of different colors (or wavelengths). For example, any one of the first organic light emitting layer, the second organic light emitting layer and the third organic light emitting layer may provide light of the first color (e.g., green), another organic light emitting layer may provide light of the second color (e.g., red), and the other organic light emitting layer may provide light of the third color (e.g., blue).

A first charge generation layer may be located between the first stack layer and the second stack layer to supply charges to the second stack layer and electrons to the first stack layer. The first charge generation layer may include an n-type charge generation layer that supplies electrons to the first stack layer and a p-type charge generation layer that supplies holes to the second stack layer. The n-type charge generation layer may include a dopant of a metallic material.

A second charge generation layer may be located between the second stack layer and the third stack layer to supply charges to the third stack layer and electrons to the second stack layer. The second charge generation layer may include an n-type charge generation layer that supplies electrons to the second stack layer and a p-type charge generation layer that supplies holes to the third stack layer.

The first stack layer of the light emitting stack IL may be located on the first electrodes AND, the pixel defining layers PDL and the separator SPR. Due to the separator SPR described above, the first stack layer of the light emitting stack IL may be broken between neighboring subpixels SP1 through SP3. The second stack layer of the light emitting stack IL may be located on the first stack layer. Due to the separator SPR described above, the second stack layer may be broken between the neighboring subpixels SP1 through SP3. The third stack layer of the light emitting stack IL may be located on the second stack layer. The third stack layer of the light emitting stack IL may not be broken by the separator SPR and may cover the second stack layer.

In the three-tandem structure, the separator SPR may be a structure for breaking the first charge generation layer and the second charge generation layer of the display element layer EML between neighboring subpixels SP1 through SP3. In addition, in the two-tandem structure, the separator SPR may be a structure for breaking a charge generation layer located between a lower stack layer and an upper stack layer.

The second electrode CAT may be located on the light emitting stack IL. For example, the second electrode CAT may be located on the third stack layer of the light emitting stack IL. The second electrode CAT may be located on the third stack layer of the light emitting stack IL without being broken by the separator SPR. The second electrode CAT may include a semi-transmissive conductive material such as magnesium (Mg), silver (Ag), or an alloy of Mg and Ag. In this case, the light output efficiency of each of the first through third subpixels SP1 through SP3 may be increased by a microcavity.

The encapsulation layer TFE may be located on the display element layer EML. The encapsulation layer TFE may include one or more inorganic layers TFE1 and TFE2 to prevent the penetration of oxygen or moisture into the display element layer EML. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be located on the second electrode CAT. The first encapsulating inorganic layer TFE1 may be a multilayer in which one or more inorganic layers selected from silicon nitride (SiNₓ), silicon oxynitride (SiON), and silicon oxide (SiOₓ) are alternately stacked. The first encapsulating inorganic layer TFE1 may be formed by a chemical vapor deposition process.

The encapsulating organic layer TFE2 may be a monomer. Alternatively, the encapsulating organic layer TFE2 may be an organic layer such as acryl resin, epoxy resin, phenolic resin, polyamide resin, or polyimide resin.

The second encapsulating inorganic layer TFE3 may be located on the encapsulating organic layer TFE2. The second encapsulating inorganic layer TFE3 may be a multilayer in which one or more inorganic layers selected from silicon nitride (SiNₓ), silicon oxynitride (SiON), and silicon oxide (SiOₓ) are alternately stacked. The second encapsulating inorganic layer TFE3 may be formed by a chemical vapor deposition process.

An organic layer APL may be a layer for increasing the interfacial adhesion between the encapsulation layer TFE and the optical layer OPL. The organic layer APL may be an organic layer such as acryl resin, epoxy resin, phenolic resin, polyamide resin, or polyimide resin.

The optical layer OPL includes a plurality of color filters CF1 through CF3, a plurality of lenses LNS, and a filling layer FIL. The color filters CF1 through CF3 may include first through third color filters CF1 through CF3. The first through third color filters CF1 through CF3 may be located on the organic layer APL.

The first color filter CF1 may overlap the first emission area EA1 of the first subpixel SP1. The first color filter CF1 may transmit light of the first color (e.g., light in the red wavelength band). Therefore, the first color filter CF1 may transmit the light of the first color among the light emitted from the light emitting stack IL of the first emission area EA1.

The second color filter CF2 may overlap the second emission area EA2 of the second subpixel SP2. The second color filter CF2 may transmit light of the second color (e.g., light in the green wavelength band). Therefore, the second color filter CF2 may transmit the light of the second color among the light emitted from the light emitting stack IL of the second emission area EA2.

The third color filter CF3 may overlap the third emission area EA3 of the third subpixel SP3. The third color filter CF3 may transmit light of the third color (e.g., light in the blue wavelength band). Therefore, the third color filter CF3 may transmit the light of the third color among the light emitted from the light emitting stack IL of the third emission area EA3.

The lenses LNS may be located on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape, but embodiments of the present specification are not limited thereto.

The filling layer FIL may be located on the lenses LNS. The filling layer FIL may have a selected refractive index so that light can travel in the third direction DR3 at an interface between the lenses LNS and the filling layer FIL. In addition, the filling layer FIL may be a planarization layer. The filling layer FIL may be an organic layer such as acryl resin, epoxy resin, phenolic resin, polyamide resin, or polyimide resin.

The cover layer CVL may be located on the filling layer FIL. The cover layer CVL may be a glass substrate or polymer resin such as resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is polymer resin such as resin, it may be directly applied on the filling layer FIL.

The polarizer POL may be located on a surface of the cover layer CVL. The polarizer POL may be a structure for preventing visibility reduction due to the reflection of external light. The polarizer POL may include a linear polarizer and a phase retardation film. For example, the phase retardation film may be a quarter-wave plate (λ/4 plate), but embodiments of the present specification are not limited thereto. If visibility reduction due to the reflection of external light is sufficiently improved by the first through third color filters CF1 through CF3, the polarizer POL may be omitted.

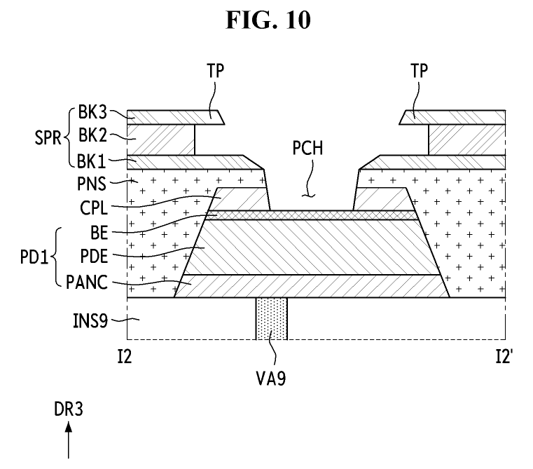

FIG. 10 is a cross-sectional view of an example of the display panel 100 taken along the line I2-I2’ of FIG. 4.

FIG. 10 illustrates a first pad located in the non-display area NDA.

The first pad may include a pad connection electrode PANC, a pad electrode, and a buffer electrode BE.

The pad connection electrode PANC may be located on the ninth insulating layer INS9. The pad connection electrode PANC may include the same material as the connection electrodes ANC described above.

The pad electrode may be located on the pad connection electrode PANC. The pad electrode may contact (or directly contact) the pad connection electrode PANC. The pad electrode may include the same material as the reflective electrodes RL described above.

The buffer electrode BE may be located on the pad electrode. The buffer electrode BE may contact (or directly contact) the pad electrode. The buffer electrode BE may prevent an oxide layer from being formed on the pad electrode. For example, when the pad electrode includes a material including silver (Ag), an oxide layer such as silver oxide (AgO) may be formed on the pad electrode. Because the oxide layer has an irregular surface, when a heterogeneous layer (e.g., a terminal (or bump) of the data driver 700) is formed on the pad electrode, the adhesion between the pad electrode and the heterogeneous layer may be weakened. In this case, the heterogeneous layer on the pad electrode may be lifted without being bonded to the pad electrode. The buffer electrode BE may relatively improve the adhesion between the pad electrode and the heterogeneous layer on the pad electrode by preventing the formation of an oxide layer such as silver oxide on the pad electrode. The buffer electrode BE may have a thickness of 10 Å (or about 10 Å) or less. The buffer electrode BE may include titanium nitride (TiN).

A capping layer CPL may be located on the buffer electrode BE. For example, the capping layer CPL may be located on edges of the buffer electrode BE. In other words, the capping layer CPL may have a pad contact hole PCH penetrating the capping layer CPL in the third direction DR3. A central portion of the buffer electrode BE may be exposed to the outside by the pad contact hole PCH. A terminal (or bump) of the data driver 700 described above may be connected to the buffer electrode BE through the pad contact hole PCH of the capping layer.

The planarization layer PNS may be located on the capping layer CPL.

The separator SPR having the tips TP may be located on the planarization layer PNS. The separator SPR may include the first bank BK1, the second bank BK2, and the third bank BK3 as described above.

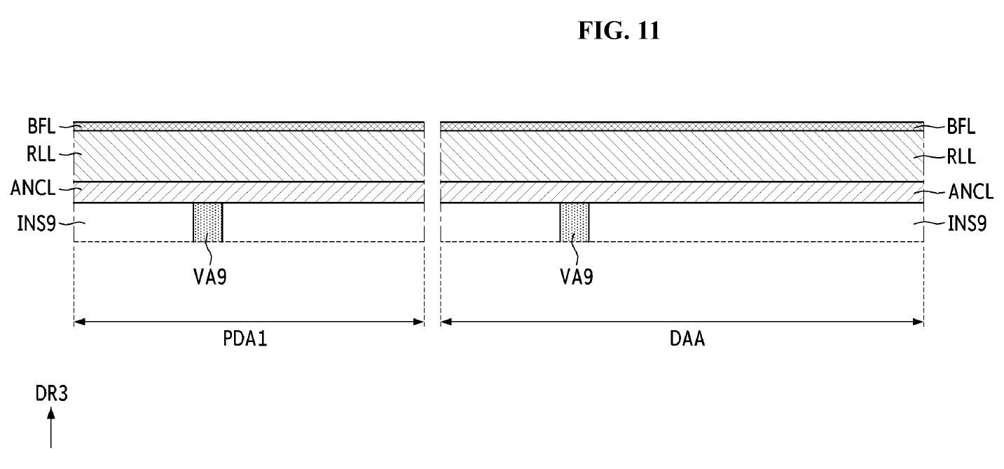

FIGS. 11, 12, 13, 14, 15, 16, 17, 18, 19 and 20 are process views illustrating a method of fabricating a display device according to some embodiments. For example, FIGS. 11 through 20 may be process cross-sectional views illustrating a method of fabricating the display device of FIGS. 9 and 10.

First, as illustrated in FIG. 11, a ninth insulating layer INS9 may be formed on a semiconductor substrate SSUB having a display area DAA and a non-display area NDA (e.g., a first pad portion PDA1 of the non-display area NDA), and ninth via electrodes VA9 may be formed in via holes of the ninth insulating layer INS9. Then, a connection electrode layer ANCL may be formed on the ninth insulating layer INS9 to contact the ninth via electrodes VA9. For example, the connection electrode layer ANCL may be formed on the entire surface of the semiconductor substrate SSUB including the ninth insulating layer INS9 and the ninth via electrodes VA9 to cover the ninth insulating layer INS9 and the ninth via electrodes VA9. Next, a reflective electrode layer RLL may be formed on the connection electrode layer ANCL. For example, the reflective electrode layer RLL may be formed on the entire surface of the semiconductor substrate SSUB including the connection electrode layer ANCL to cover the connection electrode layer ANCL. Next, a buffer layer BFL may be formed on the reflective electrode layer RLL. For example, the buffer layer BFL may be formed on the entire surface of the semiconductor substrate SSUB including the reflective electrode layer RLL to cover the reflective electrode layer RLL.

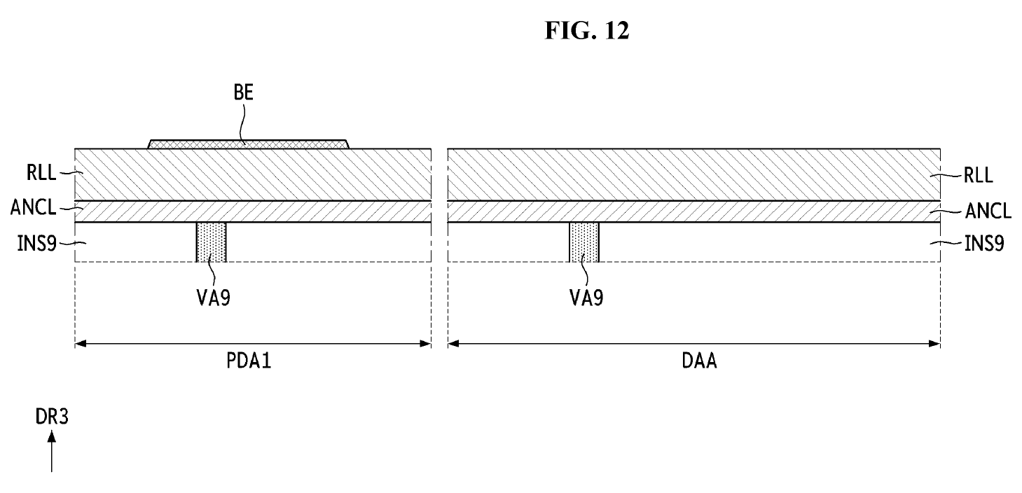

Next, as illustrated in FIG. 12, the buffer layer BFL may be patterned through a photoresist process and an etching process to form a buffer electrode BE in the first pad portion PDA1. For example, the buffer layer BFL of the display area DAA may be removed by patterning the buffer layer BFL.

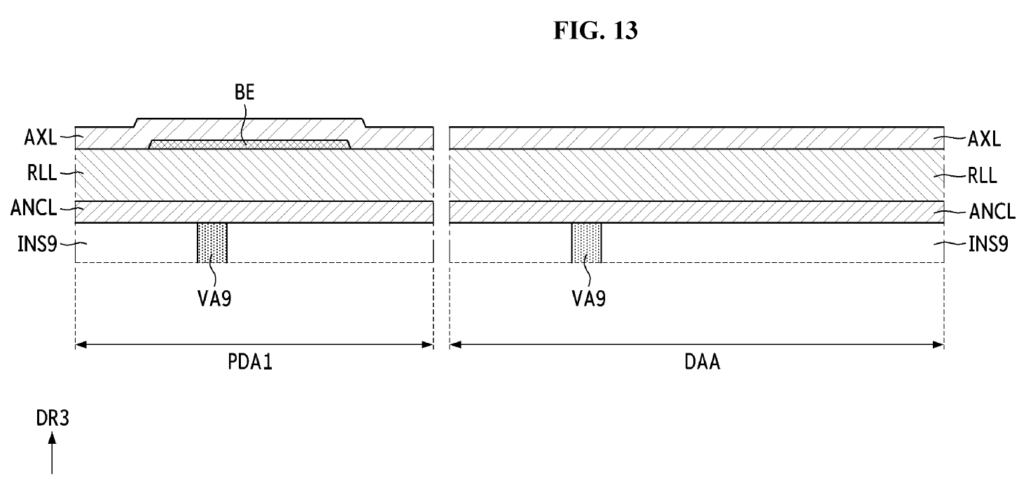

Next, as illustrated in FIG. 13, an auxiliary layer AXE may be formed on the buffer electrode BE and the reflective electrode layer RLL. For example, the auxiliary layer AXL may be formed on the entire surface of the semiconductor substrate SSUB including the buffer electrode BE and the reflective electrode layer RLL to cover the buffer electrode BE and the reflective electrode layer RLL.

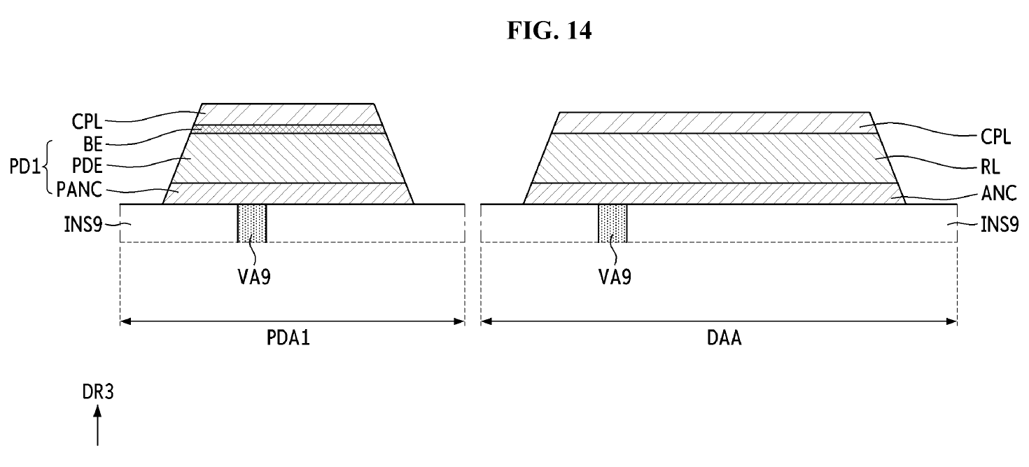

Next, as illustrated in FIG. 14, the connection electrode layer ANCL, the reflective electrode layer RLL, and the auxiliary layer AXL may be patterned through a photoresist process and an etching process to form a connection electrode ANC, a reflective electrode RL and a capping layer CPL in the display area DAA and form a pad connection electrode PANC, a pad electrode PDE, a buffer electrode BE and a capping layer CPL in the first pad portion PDA1. For example, a first pad PD1 and the capping layer CPL on the first pad PD1 may be formed in the first pad portion PDA1.

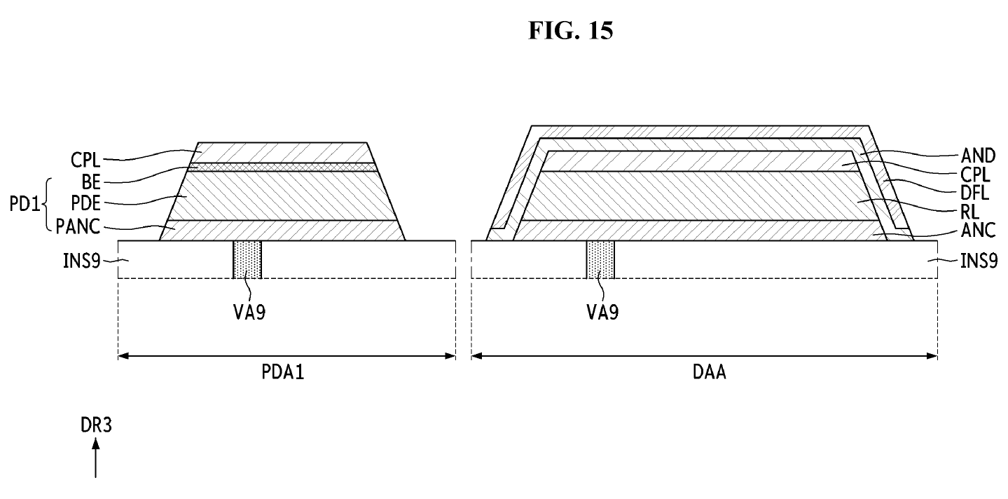

Next, as illustrated in FIG. 15, a first electrode AND may be formed on the capping layer CPL of the display area DAA through a photoresist process and an etching process, and a defining layer DFL may be formed on the first electrode AND. The first electrode AND may be formed on an upper surface of the capping layer CPL of the display area DAA, side surfaces of the capping layer CPL of the display area DAA, side surfaces of the reflective electrode RL, and side surfaces of the connection electrode ANC. The defining layer DFL may be formed on an upper surface of the first electrode AND and side surfaces of the first electrode AND.

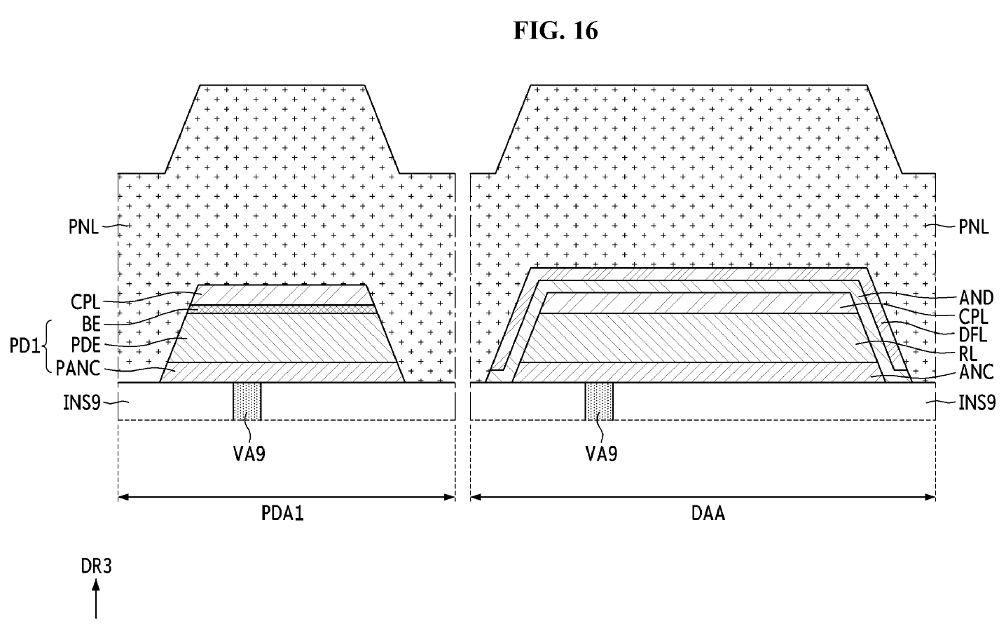

Next, as illustrated in FIG. 16, an intermediate layer PNL may be formed on the capping layer CPL, the ninth insulating layer INS9, and the defining layer DFL. For example, the intermediate layer PNL may be formed on the entire surface of the semiconductor substrate SSUB including the capping layer CPL, the ninth insulating layer INS9, and the defining layer DFL to cover the capping layer CPL, the ninth insulating layer INS9, and the defining layer DFL. At this time, the intermediate layer PNL may have bends along steps of structures under the intermediate layer PNL. Here, a lowest portion of the intermediate layer PNL may be higher than a highest portion of the defining layer DFL.

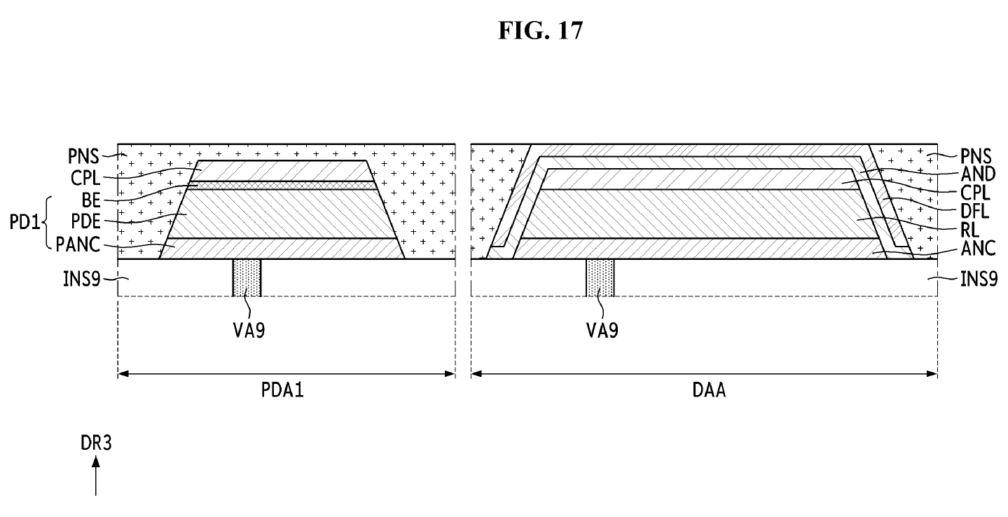

Next, as illustrated in FIG. 17, the intermediate layer PNL above the defining layer DFL may be removed to form a planarization layer PNS. For example, the intermediate layer PNL may be planarized by removing the intermediate layer PNL through chemical mechanical polishing. In other words, the intermediate layer PNL may be planarized by removing the intermediate layer PNL until the highest portion of the defining layer DFL is exposed. An upper surface of the planarization layer PNS may be located at the same (or substantially the same) height as the highest portion of the defining layer DFL.

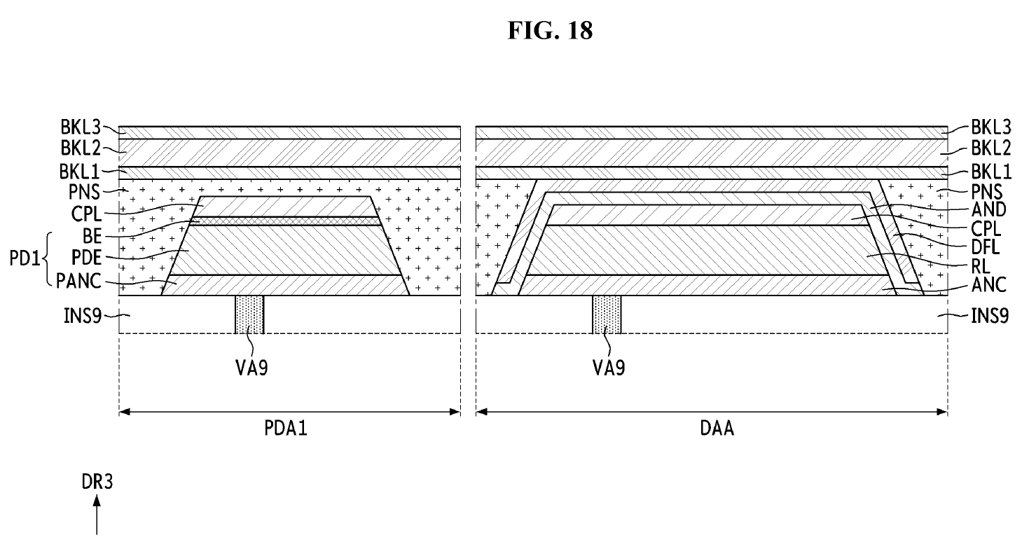

Next, as illustrated in FIG. 18, a first bank layer BKL1 may be formed on the planarization layer PNS and the exposed defining layer DFL, a second bank layer BKL2 may be formed on the first bank layer BKL1, and a third bank layer BKL3 may be formed on the second bank layer BKL2.

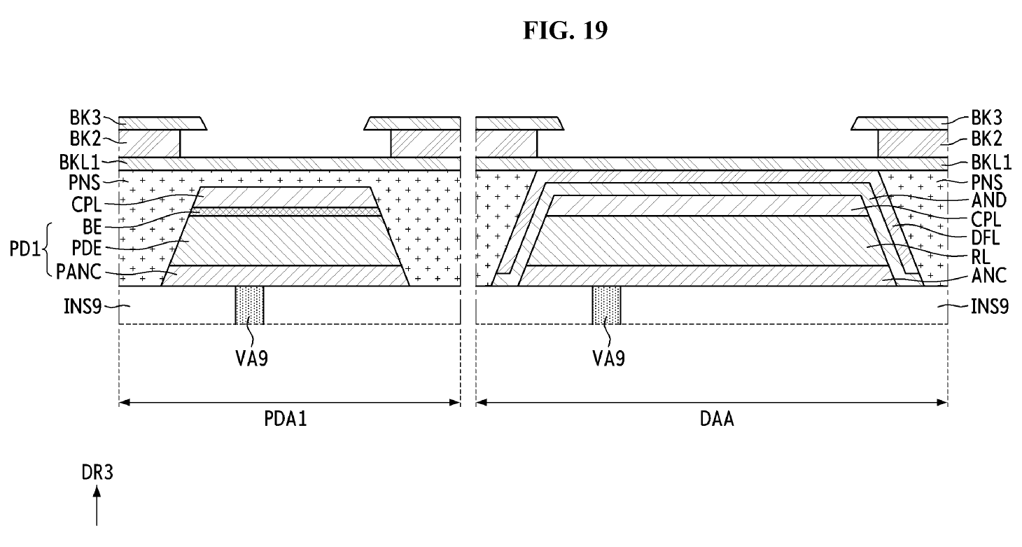

Next, as illustrated in FIG. 19, the second bank layer BKL2 and the third bank layer BKL3 may be patterned through a photoresist process and an etching process to form a second bank BK2 and a third bank BK3. At this time, because the second bank layer BKL2 located below the third bank layer BKL3 has a higher etch rate than the third bank layer BKL3, it may be etched faster than the third bank layer BKL3 during the etching process. Accordingly, after the etching (e.g., over-etching) is completed, the area of the second bank BK2 may become smaller than the area of the third bank BK3. Therefore, a structure including the second bank BK2 and the third bank BK3 may have a reverse tapered shape. As the third bank layer BKL3 and the second bank layer BKL2 are patterned as described above, the first bank layer BKL1 may be exposed.

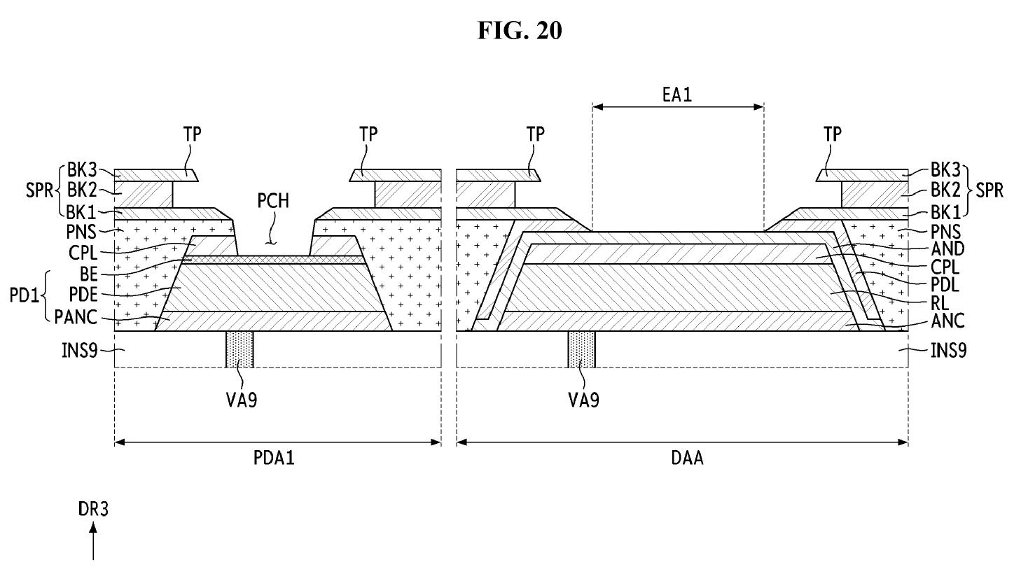

Next, as illustrated in FIG. 20, the first bank layer BKL1, the planarization layer PNS, the defining layer DFL, and the capping layer CPL may be etched and patterned together through a photoresist process and an etching process to form a first bank BK1, a pixel defining layer PDL, and a pad contact hole PCH. For example, the pixel defining layer PDL defining each of a first emission area EA1, a second emission area EA2 and a third emission area EA3 may be formed, a separator SPR including the first through third banks BK1 through BK3 may be formed, and the pad contact hole PCH exposing the buffer electrode BE may be formed. Accordingly, the first electrode AND may be exposed in each subpixel SP1, SP2 or SP3 through the first emission area EA1, the second emission area EA2, or the third emission area EA3.

Next, as illustrated in FIG. 8, a light emitting stack IL may be formed on the first electrodes AND, the pixel defining layers PDL and the separator SPR, a second electrode CAT may be formed on the light emitting stack IL, and an encapsulation layer TFE may be formed on the second electrode CAT. Here, the light emitting stack IL may be separated for each subpixel SP1, SP2 or SP3 by the separator SPR.

According to some embodiments, because the reflective electrode RL of the display area DAA and the pad electrode PDE of the non-display area NDA (e.g., the first pad portion PDA1) can be formed simultaneously or concurrently, the number of masks needed to fabricate the display device 10 can be relatively reduced. Therefore, the fabrication cost of the display device 10 can be relatively reduced.

The display device 10 according to some embodiments can be applied to various electronic devices. An electronic device according to some embodiments includes the above-described display device 10 and may further include modules or devices having other additional functions, in addition to the display device 10.

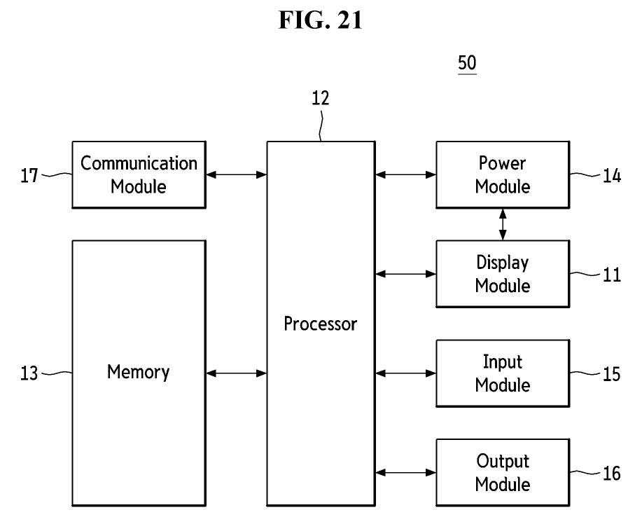

FIG. 21 is a block diagram of an electronic device 50 according to some embodiments. Referring to FIG. 21, the electronic device 50 according to some embodiments may include a display module 11, a processor 12, a memory 13, and a power module 14. The electronic device 50 may further include an input module 15, a non-image output module 16, and/or a communication module 17.

The electronic device 50 may output various information in the form of images through the display module 11. When the processor 12 executes an application stored in the memory 13, image information provided by the application may be provided to a user through the display module 11. The power module 14 may include a power supply module such as a power adapter or a battery device and a power conversion module which generates power necessary for the operation of the electronic device 50 by converting power supplied by the power supply module. The input module 15 may provide input information to the processor 12 and/or the display module 11. The non-image output module 16 may receive non-image information, such as sound, haptic and light, from the processor 12 and provide the information to a user. The communication module 17 is a module that is responsible for transmitting and receiving information between the electronic device 50 and an external device and may include a receiving unit and a transmitting unit.

At least one of the elements of the electronic device 50 described above may be included in a display device according to the embodiments described above. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 50.

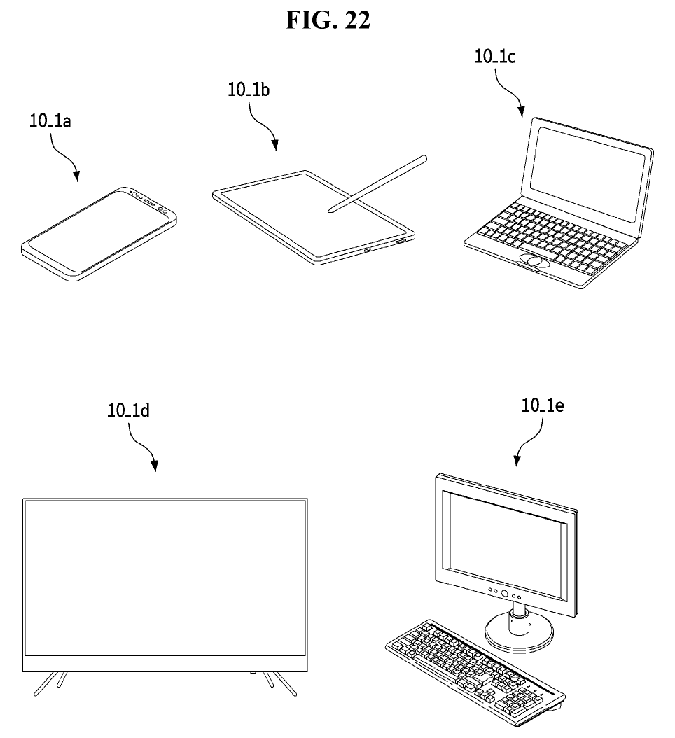

FIGS. 22, 23, and 24 are schematic diagrams of electronic devices according to various embodiments. FIGS. 22 through 24 illustrate examples of various electronic devices to which a display device 10 according to some embodiments is applied.

FIG. 22 illustrates a smartphone 10_1a, a tablet PC 10_1b, a laptop 10_1c, a television 10_1d, and a desk monitor 10_1e as examples of electronic devices.

The smartphone 10_1a may include an input module such as a touch sensor and a communication module in addition to a display module 11. The smartphone 10_1a may process information received through the communication module or other input modules and display the information through a display module of a display device.

Like the smartphone 10_1a, the tablet PC 10_1b, the laptop 10_1c, the television 10_1d, and the desk monitor 10_1e may also include a display module and an input module and may further include a communication module in some cases.

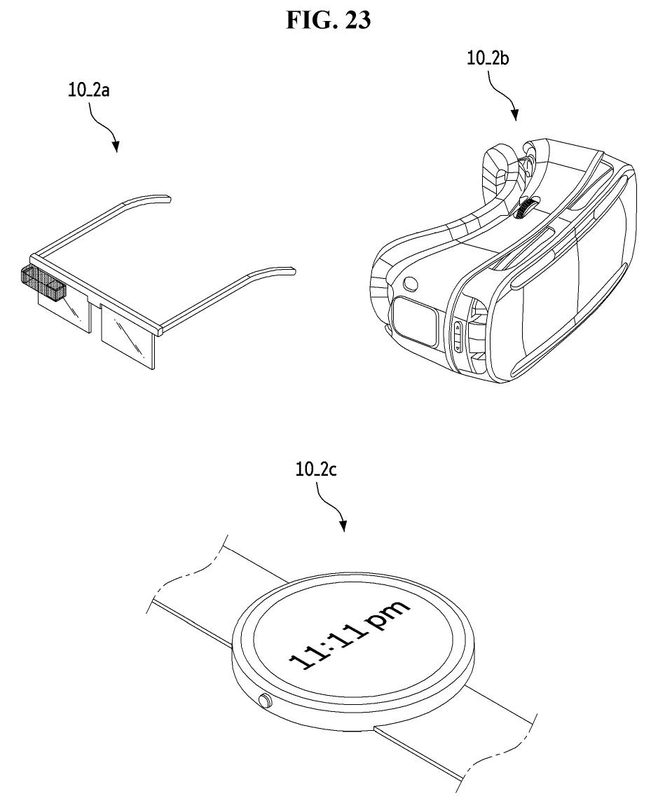

FIG. 23 illustrates a case where an electronic device including a display module is applied to a wearable electronic device. The wearable electronic device may be smart glasses 10_2a, a head mounted display 10_2b, a smart watch 10_2c, or the like.

The smart glasses 10_2a and the head mounted display 10_2b may include a display module which outputs a display image and a reflector which provides the output display screen to a user’s eyes by reflecting the output display screen. Accordingly, a screen of virtual reality or augmented reality can be provided to the user.

The smart watch 10_2c may include a biometric sensor as an input device and may provide biometric information recognized by the biometric sensor to a user through a display module.

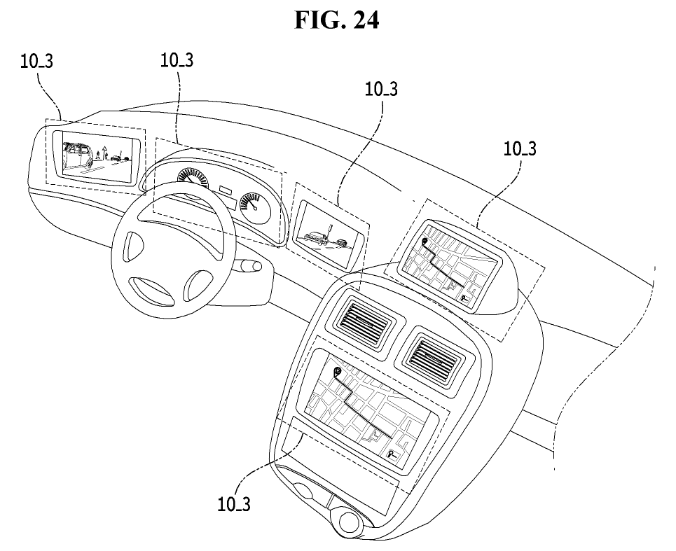

FIG. 24 illustrates a case where an electronic device including a display module is applied to a vehicle. For example, an electronic device 10_3 may be applied to an instrument panel, center fascia, etc. of a vehicle, may be applied to a center information display (CID) located on a dashboard of the vehicle, or may be applied to a room mirror display replacing a side mirror.

In concluding the detailed description, those skilled in the art will appreciate that many variations and modifications can be made to the disclosed embodiments without departing from the principles of the present invention. Therefore, the disclosed embodiments of the invention are used in a generic and descriptive sense only and not for purposes of limitation.

What is claimed is:

1. A display device comprising:
a substrate having a display area and a non-display area;
a connection electrode on the display area of the substrate;
a reflective electrode on the connection electrode;
a capping layer on the reflective electrode;
a first electrode on the capping layer;
a pixel defining layer on the first electrode and defining an emission area which exposes the first electrode;
a light emitting stack on the first electrode and the pixel defining layer;
a second electrode on the light emitting stack; and
a pad on a pad portion of the non-display area of the substrate,
wherein the pad comprises a pad electrode comprising the same material as the reflective electrode.

2. The display device of claim 1, wherein the pad further comprises:
a pad connection electrode between the substrate and the pad electrode; and
a buffer electrode on the pad electrode.

3. The display device of claim 2, wherein the capping layer is further located on edges of the buffer electrode.

4. The display device of claim 3, wherein the capping layer has a pad contact hole exposing the buffer electrode.

5. The display device of claim 1, wherein the capping layer is between the reflective electrode and the first electrode.

6. The display device of claim 1, wherein the capping layer comprises a silicon oxide-based inorganic layer.

7. The display device of claim 2, wherein the buffer electrode has a thickness of 10 Å or less.

8. The display device of claim 2, wherein the buffer electrode comprises titanium nitride.

9. The display device of claim 1, wherein the capping layer has a same thickness in emission areas configured to emit light of different colors.

10. The display device of claim 1, wherein the first electrode is on an upper surface of the capping layer, side surfaces of the capping layer, side surfaces of the reflective electrode, and side surfaces of the connection electrode.

11. The display device of claim 1, wherein a thickness of the first electrode on the side surfaces of the capping layer is different from a thickness of the first electrode on the upper surface of the capping layer.

12. The display device of claim 1, wherein the thickness of the first electrode on the side surfaces of the capping layer is smaller than the thickness of the first electrode on the upper surface of the capping layer.

13. The display device of claim 1, further comprising a planarization layer on the pixel defining layer.

14. The display device of claim 13, further comprising a separator on the planarization layer.

15. The display device of claim 14, wherein the separator comprises a plurality of banks having different areas.

16. The display device of claim 14, wherein the light emitting stack is further located on the separator.

17. The display device of claim 16, wherein the light emitting stack is cut along the separator.

18. An electronic device comprising a display device which comprises a screen, wherein the display device comprises:
a substrate having a display area and a non-display area;
a connection electrode on the display area of the substrate;
a reflective electrode on the connection electrode;
a capping layer on the reflective electrode;
a first electrode on the capping layer;
a pixel defining layer on the first electrode and defining an emission area which exposes the first electrode;
a light emitting stack on the first electrode and the pixel defining layer;
a second electrode on the light emitting stack; and
a pad located on a pad portion of the non-display area of the substrate,
wherein the pad comprises a pad electrode comprising a same material as the reflective electrode.

19. The electronic device of claim 18, wherein the electronic device is one of a smartphone, a tablet, a laptop, a television, a desk monitor, smart glasses, a smart watch, a head mounted display, or a vehicle.

20. A method of fabricating a display device, the method comprising:
forming a connection electrode layer on a substrate having a display area and a non-display area;
forming a reflective electrode layer on the connection electrode layer;
forming a buffer electrode layer on the reflective electrode layer;
forming a buffer electrode in a pad portion of the non-display area by patterning the buffer electrode layer;
forming an auxiliary layer on the buffer electrode and the reflective electrode layer; and
forming a connection electrode, a reflective electrode and a capping layer in the display area and forming a pad connection electrode, a pad electrode and a capping layer in the pad portion by patterning the connection electrode layer, the reflective electrode layer, and the auxiliary layer.
